(19) United States
(12) Patent Application Publication
(10) Pub. No.: US 2008/0157145 A1
(43) Pub. Date: Jul. 3, 2008

(54) Method of fabricating image sensor

(76) Inventor: Dong-Bin Park, Daejeon (KR)

Correspondence Address: SHERR & NOURSE, PLLC, 620 HERNDON PARKWAY, SUITE 200, HERNDON, VA, 20170, US

(21) Appl. No.: 11/953,593

(22) Filed: Dec. 10, 2007

(30) Foreign Application Priority Data
Dec. 29, 2006 (KR) 10-2006-0137326

(51) Int. Cl. H01L 31/113; H01L 31/18

(52) U.S. Cl. 257/292; 438/59; 257/E31.085

(57) ABSTRACT

A method of fabricating a CMOS image sensor can include forming a first conductive type epitaxial layer on a heavily doped first conductive type substrate, forming a device isolation layer on a prescribed portion of the epitaxial layer, forming a gate electrode on an active area of the epitaxial layer defined by the device isolation layer, forming a second conductive type first diffusion area to be connected to a surface of the epitaxial layer by carrying out ion implantation on the epitaxial layer for forming a photodiode therein, and forming a second conductive type second diffusion area by carrying out ion implantation on a boundary between the gate electrode and the first diffusion area. Accordingly, the gate and the depletion region of the photodiode are connected, thereby suppressing noise generation by enabling electrons trapped by defects to move freely via the depletion area.

The present application claims priority under 35 U.S.C. 119 to Korean Patent Application No. 10-2006-0137326 (filed on Dec. 29, 2006), which is hereby incorporated by reference in its entirety.

### BACKGROUND

An image sensor is a device for converting an optical image to an electric signal. An image sensor may be classified as a charge coupled device (CCD) or a CMOS image sensor. A CCD image sensor may include MOS (metal-oxide-silicon) capacitors provided closer in spatial proximity to each other whereby carriers may be stored in the capacitor to be transported. A CMOS image sensor may include a switching system having a plurality of MOS transistors corresponding to pixels using CMOS technology, which uses a control circuit and a signal processing circuit as a peripheral circuit, to sequentially detect outputs using the MOS transistors.

A pinned photodiode is a device that may generate and accumulate photo-generated charges by sensing incoming light by a CCD image sensor or a CMOS image sensor. The pinned diode may have a PNP or NPN junction structure buried within a substrate to be called a buried photodiode.

The pinned diode may have greater advantages than those of a photodiode having a source/drain PN junction structure, a MOS capacitor structure or the like. One such advantage lies in its capability to convert incident photons to electrons due to the extendable depth of a depletion layer (high quantum efficiency). In particular, in a pinned diode having a PNP junction structure, as an n-region becomes completely depleted to form a depletion layer including two p-regions having an n-region inserted in-between. Accordingly, such a pinned diode may have enhanced photosensitivity as well as a capability of raising photo-generated charge generation efficiency (quantum efficiency) by increasing a depth of the depletion layer.

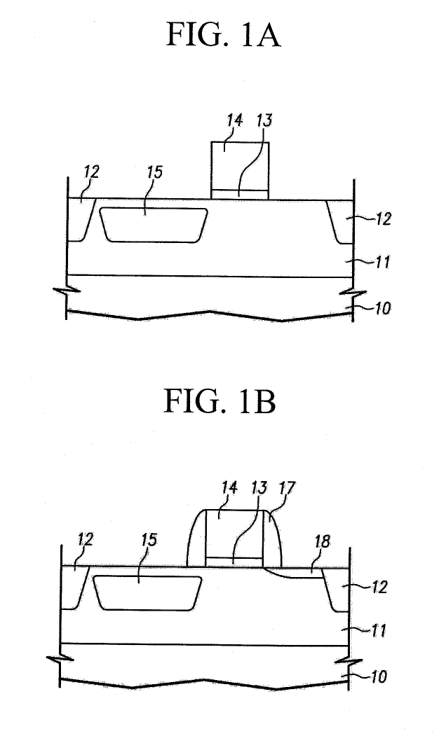

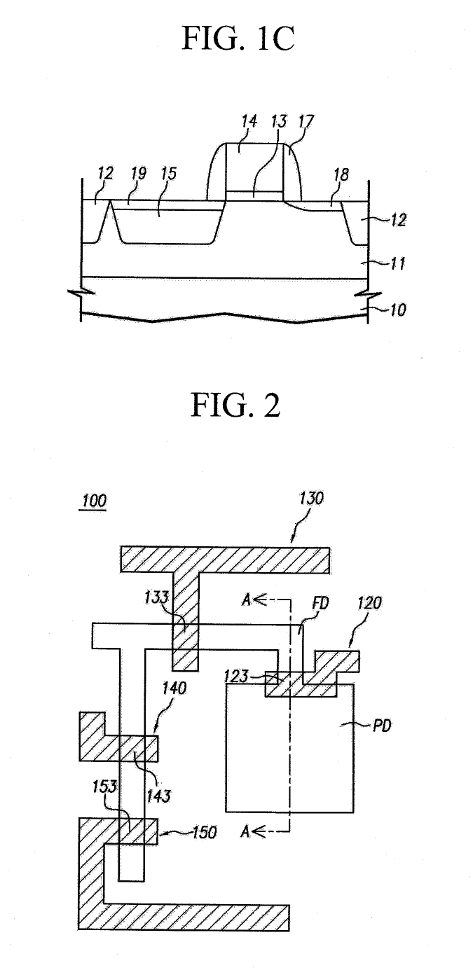

According to a related art is explained as follows. FIGS. 1A to 1C are cross-sectional diagrams for a method of fabricating a CMOS image sensor according to a related art.

As illustrated in example FIG. 1A, a method of fabricating a CMOS image sensor may include forming p− epitaxial layer 11 on and/or over p+ semiconductor substrate 10. Device isolation layer 12 having a channel stop region may then be formed in semiconductor substrate 10 by implanting BF₂ ions. Gate insulating layer 13 and gate 14 are then formed on and/or over semiconductor substrate 10.

Optionally, a non-reflective coating layer for preventing diffused reflection can be formed on and/or over gate 14. Gate 14 may be a gate of a transfer transistor. A reset gate, a drive gate, a select gate and the like may also be formed. A conductive layer of gate 14 can include at least one of a doped polysilicon layer and various kinds of silicide layers such as W-silicide, Ti-silicide, Ta-silicide, Mo-silicide, and the like.

As illustrated in example FIG. 1B, after forming an ion implantation mask, impurities may be implanted into a photodiode region of semiconductor substrate 10 to form N− diffusion region 15. Subsequently, a series of ion implantation may be carried out to form sources/drains of CMOS transistors. In particular, light ion implantation may be carried out, oxide spacer 17 is then formed on a sidewall of gate 14, and heavy ion implantation may then be carried out. Sensing node (FD area) 18 of a transfer transistor may be heavily ion-implanted to reduce overlapped capacitance between gate 14 of the transfer transistor and sensing node 18.

As illustrated in example FIG. 1C, a mask pattern may then be formed to expose only an active region for forming a photodiode. A Po-type diffusion region 19 may then be formed by implanting ions into the active region. After the mask pattern has been removed, dopants may then be diffused by carrying out annealing at a temperature of about 900° C. for 20 minutes in a nitrogen ambience.

However, in such a photodiode, additional energy such as neighbor thermal energy and the like may be given to electrons trapped by defects existing within the photodiode after a channel of the gate has been opened. So, those electrons work as noise.

### SUMMARY

Embodiments relate to a method of fabricating a CMOS image sensor by which noise generated by electrons trapped in defect within a photodiode can be prevented.

Embodiments relate to a method of fabricating a CMOS image sensor by which a channel of a transfer gate can be inverted using electrons trapped in defect.

Embodiments relate to a method of fabricating an image sensor that can include at least one of the following steps: forming an epitaxial layer over a semiconductor substrate; forming a device isolation layer in a prescribed portion of the epitaxial layer; forming a gate electrode over an active region of the epitaxial layer defined by the device isolation layer; forming a second conductive type first diffusion area to be connected to a surface of the epitaxial layer by carrying out ion implantation on the epitaxial layer for forming a photodiode therein; and then forming a second conductive type second diffusion area by carrying out ion implantation on a boundary between the gate electrode and the first diffusion region.

Embodiments relate to a method of fabricating an image sensor that can include at least one of the following steps: forming a epitaxial layer having a first conductive type over a semiconductor substrate having a heavily doped first conductive type; forming a device isolation layer in the epitaxial layer; forming a gate over an active region of the epitaxial layer defined by the device isolation layer, wherein the gate is buried in the epitaxial layer to a prescribed depth; and then forming a first diffusion region having a second conductive type in a photodiode region of the epitaxial layer.

Embodiments relate to an image sensor that can include at least one of the following: an epitaxial layer having a first conductive type formed over a semiconductor substrate having a heavily doped first conductive type; a device isolation layer formed in the epitaxial layer; a trench having a predetermined depth formed in the epitaxial layer; a gate formed in the trench; and a first diffusion region having a second conductive type formed in a photodiode region of the epitaxial layer and connected to the gate. In accordance with embodiments, the gate can be formed having a predetermined thickness such that a portion of the gate projects from the uppermost surface of the epitaxial layer.

### DRAWINGS

Example FIGS. 1A to 1C illustrate a method of fabricating a CMOS image sensor.

Example FIG. 2 illustrates a unit pixel of a CMOS image sensor, in accordance with embodiments.

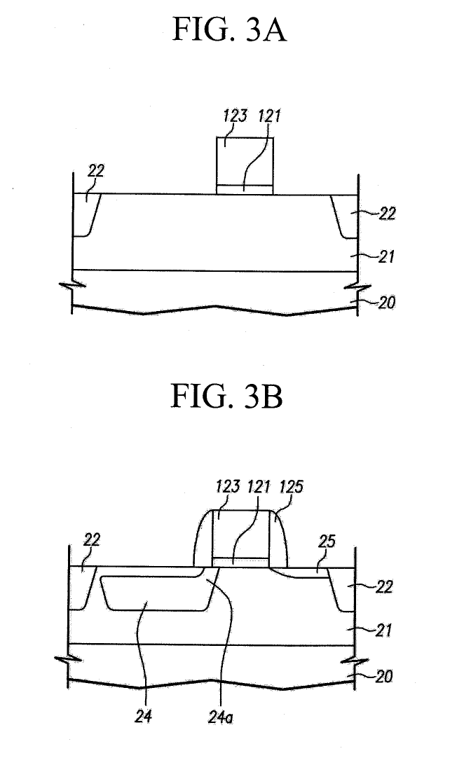

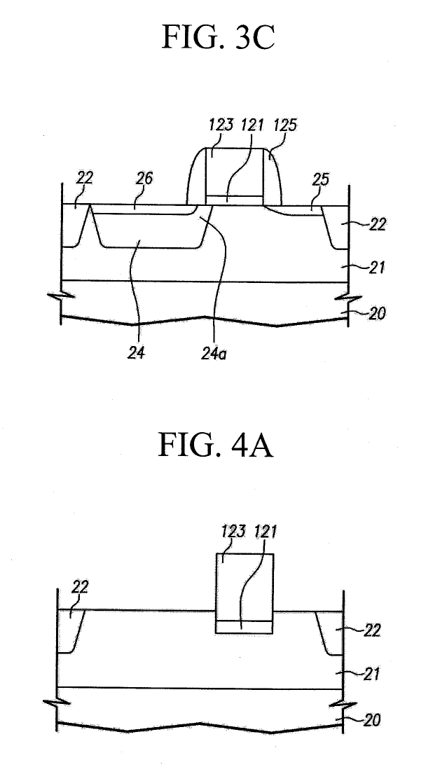

Example FIGS. 3A to 3C illustrate a method of fabricating a CMOS image sensor, in accordance with embodiments.

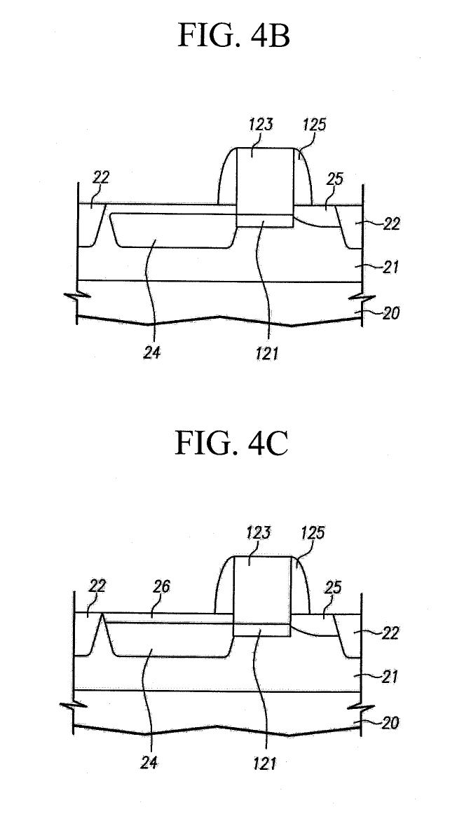

Example FIGS. 4A to 4C illustrate a method of fabricating a CMOS image sensor, in accordance with embodiments.

### DESCRIPTION

As illustrated in example FIG. 2, unit pixel 100 of a CMOS image sensor in accordance with embodiments can include an active region discriminated from a device isolation area defined by a device isolation layer. Gate 123 of transfer transistor 120, gate 133 of reset transistor 130, gate 143 of drive transistor 140, and gate 153 of select transistor 150 can be arranged to cross over the active region.

Floating diffusion area FD can be formed within an epitaxial layer to be spaced apart from an N−/Po diffusion region while gate 123 of transfer transistor 120 can be provided in-between.

Photodiode PD can have the N−/Po diffusion region in the following description. Alternatively, photodiode PD can actually have an N-diffusion region only. In this case, the N-diffusion region can be configured as a PN or NP junction diode together with the epitaxial layer underneath.

In the following description, ‘P++’ or ‘P+’ can indicate a heavily doped P-type, ‘Po’ can indicate an intermediately doped P-type, and ‘N−’ can indicate a lightly doped N-type. First and second conductive types indicate P and N or N and P, respectively.

For convenience of explanation, photodiode PD having a Po/N− diffusion region is taken as an example in the following description.

In the following description, an image sensor fabricating method is explained with reference to a photodiode and a transfer gate of a unit pixel bisected along a cutting line A-A in FIG. 2.

As illustrated in example FIG. 3A, a method of fabricating a CMOS image sensor in accordance with embodiments can include forming P-type epitaxial layer 21 on and/or over P+ semiconductor substrate 20. Device isolation layer 22 can then be formed in epitaxial layer 21 to define an active region of semiconductor substrate 20. Device isolation layer 22 can be formed by a shallow trench isolation (STI) process or by a local oxidation of silicon (LOCOS) process.

Gate insulating layer 121 and gate 123 of transfer transistor 120 can then be formed on and/or over epitaxial layer 21. In doing so, the reset gate, the drive gate, the select gate and the like illustrated in example FIG. 2 can be simultaneously formed.

As illustrated in example FIG. 3B, after an ion implantation mask has been formed, impurities can then be injected by ion implantation into a photodiode region (i.e., a region where a photodiode will be formed) of epitaxial layer 21 to form N-diffusion region 24. N-diffusion region 24a can be formed between gate 123 and N− diffusion region 24 by ion implantation. Preferably, the ion implantation can be carried out by a tilt method. N-diffusion region 24 for forming the photodiode can be extended to a bottom of one side of gate 123 by N− diffusion region 24a.

A series of ion implantations can then be carried out to form sources/drains of CMOS transistors. In particular, light ion implantation can be carried out, gate insulating layer 121 and oxide spacer 125 on a sidewall of gate insulating layer 121 and gate 123 can then be formed, and heavy ion implantation is then carried out. The heavy ion implantation can be carried out on a sensing node (FD area) 25 of a transfer gate only to reduce overlapped capacitance between gate 123 of transfer transistor 120 and sensing node 25.

As illustrated in example FIG. 3C, a mask pattern can then be formed to expose only an active region for forming a photodiode therein. Ion implantation can then be carried out on the active region to form Po diffusion region 26. So, a photodiode is then formed. After the mask pattern has been removed, dopants are diffused by annealing.

A depletion region of the photodiode becomes connected to a lower part of the gate. So, electrons trapped by defect are free to move via the depletion region. Thus, the depletion region can be used to invert a channel of the transfer gate.

As illustrated in example FIG. 4A, a method of fabricating an image sensor in accordance with embodiments can include forming P-epitaxial layer 21 on and/or over P+ semiconductor substrate 20. Device isolation layer 22 can then be formed on and/or over epitaxial layer 21 for a device isolation area to define an active region of semiconductor substrate 20. Device isolation layer 22 can be formed by a shallow trench isolation (STI) process or by a local oxidation of silicon (LOCOS) process.

After a mask pattern has been formed to expose a prescribed portion of epitaxial layer 21 of transfer gate 120, a trench can then be formed by etch using the mask pattern. After the mask pattern has been removed, gate insulating layer 121 can then be formed on and/or over a bottom of the trench. Gate 123 can then be formed on and/or over gate insulating layer 121 within the trench. In particular, gate 123 can be buried in epitaxial layer 21 to a prescribed depth such that a portion of gate 123 projects from the uppermost surface of epitaxial layer 21. Thus, gate insulating layer 121 and gate 123 are recessed into epitaxial layer 21. Subsequently, the reset gate, the drive gate, the select gate and the like illustrated in example FIG. 2 can be formed in a same manner.

As illustrated in example FIG. 4B, after an ion implantation mask has been formed, impurities can be injected into a photodiode region by ion implantation to form N-diffusion region 24. N-diffusion region 24 can be connected to a lower part of gate 123. Subsequently, a series of ion implantations can be carried out to form sources/drains of CMOS transistors. In particular, light ion implantation can be carried out, gate insulating layer 121 and oxide spacer 125 on a sidewall of gate insulating layer 121 and gate 123 are formed, and heavy ion implantation is then carried out. The heavy ion implantation can be carried out on sensing node (FD region) 25 of a transfer gate only to reduce overlapped capacitance between gate 123 of transfer transistor 120 and sensing node 25.

As illustrated in example FIG. 4C, a mask pattern can then be formed to expose only an active region for forming a photodiode therein. Ion implantation can then be carried out on the active region to form Po diffusion region 26, and thus, a photodiode is formed. After the mask pattern has been removed, dopants are diffused by annealing.

A depletion region of the photodiode can be connected to a lower part of gate 123. So, electrons trapped by defect are free to move via the depletion region. Thus, the depletion region can be used to invert a channel of the transfer gate 123.

Accordingly, embodiments can provide the following effects or advantages. First, a gate can be connected to a depletion region of a photodiode to thereby suppress noise generation by enabling electrons trapped by defects to move freely via the depletion region. Lastly a channel of the transfer gate can be enabled to be inverted using electrodes trapped by defects.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method comprising:
forming an epitaxial layer over a semiconductor substrate;
forming a device isolation layer in a prescribed portion of the epitaxial layer;
forming a gate electrode over an active region of the epitaxial layer defined by the device isolation layer;
forming a second conductive type first diffusion area to be connected to a surface of the epitaxial layer by carrying out ion implantation on the epitaxial layer for forming a photodiode therein; and then
forming a second conductive type second diffusion area by carrying out ion implantation on a boundary between the gate electrode and the first diffusion region.

2. The method of claim 1, wherein the epitaxial layer comprises an epitaxial layer having a first conductive type.

3. The method of claim 2, wherein the semiconductor substrate comprises a semiconductor substrate having a heavily doped first conductive type.

4. The method of claim 1, wherein the second diffusion area is formed by carrying out the ion implantation on the boundary between the gate electrode and the first diffusion area by a tilt method.

5. The method of claim 1, wherein the second diffusion area is extended to a lower part of one side of the gate electrode from the first diffusion region.

6. The method of claim 1, wherein the epitaxial layer and the first diffusion area comprises at least one of a PN and a NP junction diode.

7. The method of claim 1, wherein the first diffusion region comprises a first diffusion region having a second conductive type.

8. The method of claim 1, further comprising after forming the second diffusion region, forming a third diffusion region of a first conductive type.

9. The method of claim 8, wherein forming a third diffusion region comprises carrying out ion implantation on a surface of the epitaxial layer over the first diffusion region.

10. The method of claim 9, wherein the epitaxial layer, the first diffusion region and the third diffusion area comprises at least one of a PNP and a NPN junction diode.

11. The method of claim 1, wherein the device isolation layer is formed by at least one of a shallow trench isolation process and a local oxidation of silicon process.

12. A method comprising:
forming a epitaxial layer having a first conductive type over a semiconductor substrate having a heavily doped first conductive type;
forming a device isolation layer in the epitaxial layer;
forming a gate over an active region of the epitaxial layer defined by the device isolation layer, wherein the gate is buried in the epitaxial layer to a prescribed depth; and then
forming a first diffusion region having a second conductive type in a photodiode region of the epitaxial layer and connected to the gate.

13. The method of claim 12, wherein forming the gate comprises:
forming a trench having the prescribed depth in the epitaxial layer;
forming a gate insulating layer over a bottom of the trench; and then
forming the gate over the gate insulating layer in the trench,
wherein the gate projects a prescribed height from the uppermost surface of the epitaxial layer.

14. The method of claim 12, wherein the epitaxial layer and the first diffusion region comprises at least one of a PN and a NP junction diode.

15. The method of claim 12, further comprising after forming the first diffusion region, forming a third diffusion region having the first conductive type.

16. The method of claim 15, wherein forming the third diffusion region comprises carrying out ion implantation on a surface of the epitaxial layer over the first diffusion region.

17. The method of claim 16, wherein the epitaxial layer, the first diffusion region and the third diffusion region comprises at least one of a PNP and a NPN junction diode.

18. The method of claim 12, wherein the device isolation layer is formed by at least one of a shallow trench isolation process and a local oxidation of silicon process.

19. An apparatus comprising:
an epitaxial layer having a first conductive type formed over a semiconductor substrate having a heavily doped first conductive type;
a device isolation layer formed in the epitaxial layer;
a trench having a predetermined depth formed in the epitaxial layer;
a gate formed in the trench; and
a diffusion region having a second conductive type formed in a photodiode region of the epitaxial layer and connected to the gate,
wherein the gate is formed of a predetermined thickness such that a portion of the gate projects from the uppermost surface of the epitaxial layer.

20. The apparatus of claim 19, wherein the epitaxial layer and the diffusion area comprises at least one of a PN and a NP junction diode.
